(19) United States
(12) Patent Application Publication
(10) Pub. No.: US 2011/0241194 A1
(43) Pub. Date: Oct. 6, 2011

(54) Stacked Semiconductor Device Package Assemblies with Reduced Wire Sweep and Manufacturing Methods Thereof

(75) Inventors: Chia-Ching Chen, Kaohsiung City (TW); Yu-Pin Tsai, Kaohsiung City (TW)

(73) Assignee: Advanced Semiconductor Engineering, Inc.

(21) Appl. No.: 12/753,843

(22) Filed: Apr. 2, 2010

(51) Int. Cl. H01L 25/065; H01L 23/538

(52) U.S. Cl. 257/686; 257/E23.175; 257/E25.013

(57) ABSTRACT

An embodiment of a stacked package assembly includes: (1) a first semiconductor device package including: (a) a semiconductor device including back and lateral surfaces; (b) a package body including an upper surface and substantially covering the back and lateral surfaces of the device; and (c) a first conductive contact adjacent to the upper surface of the body and electrically connected to the device; (2) a second semiconductor device package disposed above the upper surface of the body; (3) a conductive bump adjacent to the first contact and to the second device package; (4) a second conductive contact external to the first and the second device packages; and (5) a conductive wire electrically connecting the first and the second device packages to the second contact, a first end of the wire adjacent to the first contact and at least partially covered by the bump.

### FIELD OF THE INVENTION

The invention relates generally to semiconductor device packages and manufacturing methods thereof. More particularly, the invention relates to stacked semiconductor device package assemblies with reduced wire sweep and manufacturing methods thereof.

### BACKGROUND

Electronic products have become progressively more complex, driven at least in part by the demand for enhanced functionality and smaller sizes. While the benefits of enhanced functionality and smaller sizes are apparent, achieving these benefits also can create problems. In particular, electronic products typically have to accommodate a high density of semiconductor devices in a limited space. For example, the space available for processors, memory devices, and other active or passive devices can be rather limited in cell phones, personal digital assistants, laptop computers, and other portable consumer products. In conjunction, semiconductor devices are typically packaged in a fashion to provide protection against environmental conditions as well as to provide input and output electrical connections. Packaging of semiconductor devices within semiconductor device packages can take up additional valuable space within electronic products. As such, there is a strong drive towards reducing footprint areas taken up by semiconductor device packages.

One approach to reducing footprint areas taken up by semiconductor device packages is to stack these packages on top of one another to form a stacked package assembly. The stacked package assembly may include wires external to packages included in the assembly that electrically connect those packages. The stacked package assembly may also be packaged to protect both these packages and their connecting wires from environmental conditions, such as by encapsulating the packages and the wires in a molding compound. Unfortunately, wire sweep (displacement of wires) may occur, for example, during the encapsulation process. This wire sweep, if unchecked, can result in shorting of adjacent wires, increased inductance of adjacent wires, and other effects. This can result in decreased electrical performance of stacked package assemblies, and in a corresponding reduction in packaging yield. In addition, to compensate for wire sweep, spacing between adjacent wires may need to be increased, which can lead to an increase in footprint size and/or a decrease in the number of available wires for electrically connecting packages in stacked package assemblies.

It is against this background that a need arose to develop the stacked package assemblies and related methods described herein.

### SUMMARY

One aspect of the invention relates to a stacked package assembly. In one embodiment, the stacked package assembly includes: (1) a first semiconductor device package including: (a) a first semiconductor device including a back surface and lateral surfaces disposed adjacent to a periphery of the first semiconductor device; (b) a first package body substantially covering the back surface and the lateral surfaces of the first semiconductor device, the first package body including an upper surface; and (c) a first conductive contact disposed adjacent to the upper surface of the first package body and electrically connected to the first semiconductor device; (2) a second semiconductor device package disposed above the upper surface of the first package body; (3) a first conductive bump disposed adjacent to the first conductive contact and to the second semiconductor device package; (4) a second conductive contact external to the first semiconductor device package and to the second semiconductor device package; and (5) a conductive wire electrically connecting the first semiconductor device package and the second semiconductor device package to the second conductive contact, a first end of the conductive wire disposed adjacent to the first conductive contact and at least partially covered by the first conductive bump.

In another embodiment, the stacked package assembly includes: (1) a first semiconductor device package including: (a) a first semiconductor device including a back surface and lateral surfaces disposed adjacent to a periphery of the first semiconductor device; (b) a first package body substantially covering the back surface and the lateral surfaces of the first semiconductor device, the first package body including an upper surface; (c) a redistribution unit adjacent to the upper surface of the first package body and extending laterally beyond the periphery of the first semiconductor device, the redistribution unit electrically connected to the first semiconductor device; and (d) a first conductive contact disposed adjacent to the upper surface of the first package body; (2) a second semiconductor device package disposed above the upper surface of the first package body; (3) a first conductive bump disposed adjacent to the first conductive contact and to the second semiconductor device package; (4) a second conductive bump disposed adjacent to the redistribution unit and to the second semiconductor device package, the second conductive bump electrically connecting the redistribution unit and the second semiconductor device package; (5) a second conductive contact external to the first semiconductor device package and to the second semiconductor device package; and (6) a first conductive wire electrically connecting the second semiconductor device package to the second conductive contact, a first end of the conductive wire disposed adjacent to the first conductive contact and at least partially covered by the first conductive bump.

Other aspects and embodiments of the invention are also contemplated. The foregoing summary and the following detailed description are not meant to restrict the invention to any particular embodiment but are merely meant to describe some embodiments of the invention.

### BRIEF DESCRIPTION OF THE DRAWINGS

For a better understanding of the nature and objects of some embodiments of the invention, reference should be made to the following detailed description taken in conjunction with the accompanying drawings. In the drawings, like reference numbers denote like elements, unless the context clearly dictates otherwise.

FIG. 1 illustrates a perspective view of stacked package assembly, according to an embodiment of the invention.

FIG. 2 illustrates a cross-sectional view of the stacked package assembly of FIG. 1, taken along line A-A of FIG. 1, according to an embodiment of the invention.

FIG. 3 illustrates an enlarged cross-sectional view of a portion of the stacked package assembly of FIG. 1 including a conductive bump, a conductive wire, and conductive contacts, according to an embodiment of the invention.

FIG. 4 illustrates a cross-sectional view of a stacked package assembly, according to another embodiment of the invention.

### DETAILED DESCRIPTION

### Definitions

The following definitions apply to some of the aspects described with respect to some embodiments of the invention. These definitions may likewise be expanded upon herein.

As used herein, the singular terms “a,” “an,” and “the” include plural referents unless the context clearly dictates otherwise. Thus, for example, reference to a conductive contact can include multiple conductive contacts unless the context clearly dictates otherwise.

As used herein, the term “set” refers to a collection of one or more components. Thus, for example, a set of layers can include a single layer or multiple layers. Components of a set also can be referred to as members of the set. Components of a set can be the same or different. In some instances, components of a set can share one or more common characteristics.

As used herein, the term “adjacent” refers to being near or adjoining. Adjacent components can be spaced apart from one another or can be in actual or direct contact with one another. In some instances, adjacent components can be connected to one another or can be formed integrally with one another.

As used herein, relative terms, such as “inner,” “interior,” “outer,” “exterior,” “top,” “bottom,” “front,” “back,” “upper,” “upwardly,” “lower,” “downwardly,” “vertical,” “vertically,” “lateral,” “laterally,” “above,” and “below,” refer to an orientation of a set of components with respect to one another, such as in accordance with the drawings, but do not require a particular orientation of those components during manufacturing or use.

As used herein, the terms “connect,” “connected,” and “connection” refer to an operational coupling or linking. Connected components can be directly coupled to one another or can be indirectly coupled to one another, such as through another set of components.

As used herein, the terms “substantially” and “substantial” refer to a considerable degree or extent. When used in conjunction with an event or circumstance, the terms can refer to instances in which the event or circumstance occurs precisely as well as instances in which the event or circumstance occurs to a close approximation, such as accounting for typical tolerance levels of the manufacturing operations described herein.

As used herein, the terms “electrically conductive” and “electrical conductivity” refer to an ability to transport an electric current. Electrically conductive materials typically correspond to those materials that exhibit little or no opposition to flow of an electric current. One measure of electrical conductivity is in terms of Siemens per meter (“S·m⁻¹”). Typically, an electrically conductive material is one having a conductivity greater than about 10⁴ S·m⁻¹, such as at least about 10⁵ S·m⁻¹ or at least about 10⁶ S·m⁻¹. Electrical conductivity of a material can sometimes vary with temperature. Unless otherwise specified, electrical conductivity of a material is defined at room temperature.

### Description of Embodiments of the Invention

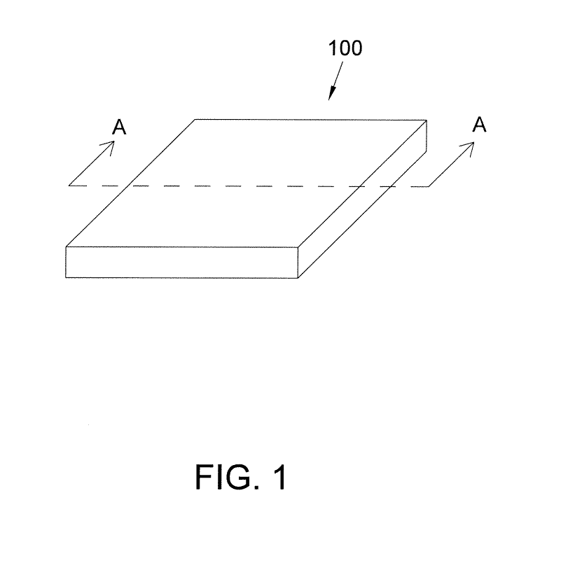

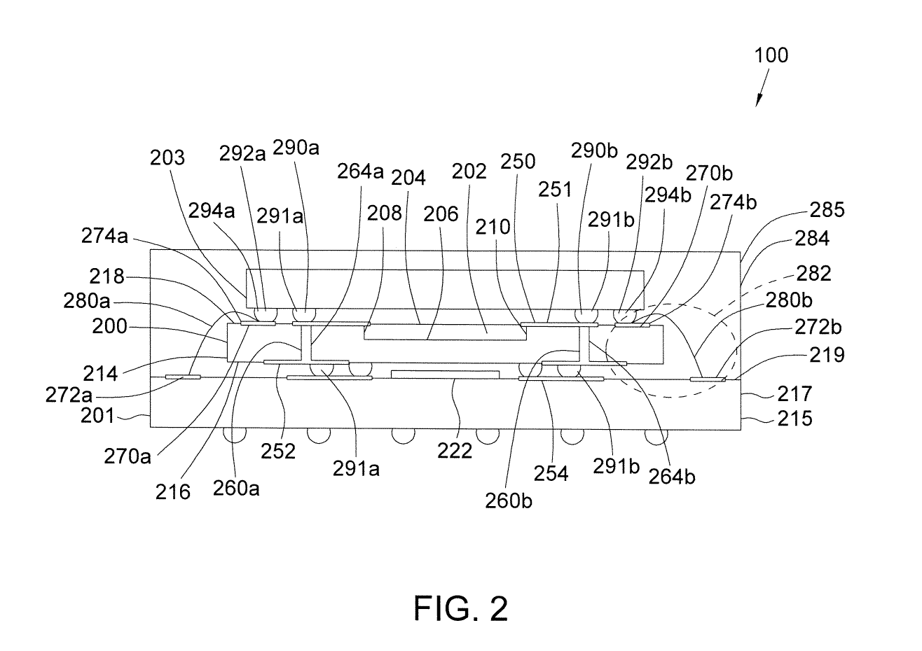

Attention first turns to FIG. 1 and FIG. 2, which illustrate a stacked package assembly 100 implemented in accordance with an embodiment of the invention. In particular, FIG. 1 illustrates a perspective view of the stacked package assembly 100, while FIG. 2 illustrates a cross-sectional view of the stacked package assembly 100, taken along line A-A of FIG. 1.

In the illustrated embodiment, sides of the stacked package assembly 100 are substantially planar and have a substantially orthogonal orientation so as to define a lateral profile that extends around substantially an entire periphery of the stacked package assembly 100. Advantageously, this orthogonal lateral profile allows a reduced overall package size by reducing or minimizing a footprint area of the stacked package assembly 100. However, it is contemplated that the lateral profile of the stacked package assembly 100, in general, can be any of a number of shapes, such as curved, inclined, stepped, or roughly textured.

Referring to FIG. 2, the stacked package assembly 100 includes a semiconductor device package 200. In one embodiment, a semiconductor device package 203 is stacked on the semiconductor device package 200, and the semiconductor device package 200 is stacked on a semiconductor device package 201. The package 200 includes a semiconductor device 202 (in an inverted orientation relative to the orientation of the stacked package assembly 100), which includes a lower surface 204, an upper surface 206, and lateral surfaces 208 and 210 disposed adjacent to a periphery of the semiconductor device 202 and extending between the lower surface 204 and the upper surface 206. In the illustrated embodiment, each of the surfaces 204, 206, 208, and 210 is substantially planar, with the lateral surfaces 208 and 210 having a substantially orthogonal orientation with respect to the lower surface 204 or the upper surface 206, although it is contemplated that the shapes and orientations of the surfaces 204, 206, 208, and 210 can vary for other implementations. As illustrated in FIG. 2, the upper surface 206 is a back surface of the semiconductor device 202, while the lower surface 204 is an active surface of the semiconductor device 202. The lower surface 204 may include contact pads that provide input and output electrical connections for the semiconductor device 202 to conductive structures included in the package 200, such as a patterned conductive layer 250 (described below). In the illustrated embodiment, the semiconductor device 202 is a semiconductor chip, although it is contemplated that the semiconductor device 202, in general, can be any active device, any passive device, or a combination thereof. While one semiconductor device is illustrated in FIG. 2, it is contemplated that additional semiconductor devices can be included for other implementations.

As illustrated in FIG. 2, the package 200 also includes a package body 214 that is disposed adjacent to the semiconductor device 202. In the illustrated embodiment, the package body 214 substantially covers or encapsulates the semiconductor device 202 in conjunction with a package body 284 (described below) to provide mechanical stability as well as protection against oxidation, humidity, and other environmental conditions. In this embodiment, the package body 214 substantially covers the upper surface 206 and the lateral surfaces 208 and 210 of the semiconductor device 202, with the lower surface 204 the semiconductor device 202 being substantially exposed or uncovered by the package body 214. The package body 214 includes a lower surface 216 and an upper surface 218. In the illustrated embodiment, each of the surfaces 216 and 218 is substantially planar, although it is contemplated that the shapes and orientations of the surfaces 216 and 218 can vary for other implementations.

In one embodiment, the package body 214 can be formed from a molding material. The molding material can include, for example, a Novolac-based resin, an epoxy-based resin, a silicone-based resin, or another suitable encapsulant. Suitable fillers can also be included, such as powdered SiO₂. The molding material may be a pre-impregnated (prepreg) material, such as a pre-impregnated dielectric material. It is also contemplated that the package body 214 can include a supporting structure in conjunction with, or in place of, a molding material. For example, the package body 214 can include a frame or an interposer, which can be formed from glass, silicon, a metal, a metal alloy, a polymer, or another suitable structural material.

As illustrated in FIG. 2, the package 200 further includes the patterned conductive layer 250 adjacent to the upper surface 218 of the package body 214. The package 200 also includes a patterned conductive layer 252 adjacent to the lower surface 216 of the package body 214. The package 200 further includes electrical interconnects 260a and 260b. The electrical interconnects 260a and 260b have lateral surfaces 264a and 264b, respectively. The electrical interconnects 260 are positioned around the semiconductor device 102, and may extend substantially vertically from the patterned conductive layer 250. The patterned conductive layers 250 and 252 may be electrically connected to one or more of the electrical interconnects 260. The lateral surfaces 264a and 264b may be substantially covered by the package body 214.

Advantageously, the patterned conductive layer 250 may serve as a redistribution network for the semiconductor device 202. For example, the package 200 may include a redistribution unit 251 that includes the patterned conductive layer 250. In one embodiment, the package 200 may provide a two-dimensional fan-out configuration in which the patterned conductive layer 250 extends substantially laterally outside of the periphery of the semiconductor device 202. For example, FIG. 2 shows electrical contacts, including conductive bumps 290a and 290b, outside of the periphery of the semiconductor device 202. The conductive bumps 290 may be electrically connected to the semiconductor device 202 via the patterned conductive layer 250. The electrical interconnects 260 of the package 200 can facilitate extending a two-dimensional fan-out to a three-dimensional fan-out by providing electrical pathways from the semiconductor device 202 to electrical contacts, including conductive bumps 291a and 291b, on the lower surface 216 of the package body 214. A three-dimensional fan-out configuration can be created by electrically connecting the conductive bumps 291 to the semiconductor device 202 through the patterned conductive layer 252, the electrical interconnects 260, and the patterned conductive layer 250. This three-dimensional fan-out configuration can advantageously increase flexibility beyond that provided by two-dimensional fan-out in terms of the arrangement and spacing of electrical contacts on both the upper side 218 and the lower side 216 of the package 200, with reduced dependence upon the arrangement and spacing of the contact pads of the semiconductor device 202. In accordance with the fan-out configuration of the package 200, the conductive bumps 290 and 291 are laterally disposed outside of the periphery of the semiconductor device 202, although it is contemplated that the conductive bumps 290 and 291, in general, can be laterally disposed within that periphery, outside of that periphery, or both.

In the illustrated embodiment, the conductive bumps 290 and 291 may be solder bumps, such as reflowed solder balls. The package 200 may be electrically connected to other packages, such as the package 201 and the package 203, through these conductive bumps. For example, the conductive bumps 290 may be disposed adjacent to the redistribution unit 251 and to the package 203, and may electrically connect the redistribution unit 251 and the package 203. Alternatively, the package 200 may be electrically connected to other packages, such as the package 201 and the package 203, through fused conductive bumps, such as solder bumps that have been combined with other conductive elements, such as other solder bumps, through reflowing.

Still referring to FIG. 2, it is contemplated that the redistribution unit 251 may be formed in situ during manufacturing as a set of redistribution layers, although it is contemplated that the redistribution unit 251 can include a preformed structure for other implementations. The redistribution unit 251 may include only the patterned conductive layer 250, or may be multi-layered. For example, in addition to the patterned conductive layer 250, the redistribution unit 251 may include a pair of dielectric layers at least partially sandwiching the patterned conductive layer 250. It is contemplated that more or less dielectric layers may be used in other implementations. In general, each of the dielectric layers can be formed from a dielectric material that is polymeric or non-polymeric. For example, at least one of the dielectric layers can be formed from polyimide, polybenzoxazole, benzocyclobutene, or a combination thereof. The dielectric layers can be formed from the same dielectric material or different dielectric materials. For certain implementations, at least one of the dielectric layers can be formed from a dielectric material that is photoimageable or photoactive, thereby reducing manufacturing cost and time by allowing patterning using photolithography.

As illustrated in FIG. 2, the package 203 may be disposed above the upper surface 218 of the package body 214 of the package 200. The package 203 may include a semiconductor device (not shown) having characteristics similar to those described previously for the semiconductor device 202. In one embodiment, conductive contacts 270a and 270b are disposed adjacent to the upper surface 218 of the package body 214. Conductive bumps 292a and 292b may be disposed adjacent to the conductive contacts 270a and 270b, respectively, and to the package 203. The conductive bumps 292 may be solder bumps, or may be fused conductive bumps similar to those previously described. One or more of the conductive contacts 270 may be electrically connected to the semiconductor device 202. Conductive wires 280a and 280b may electrically connect the conductive contacts 270a and 270b to conductive contacts 272a and 272b. In one embodiment, one or more of the conductive wires 280 may electrically connect at least one of the package 200 and the package 203 to the corresponding conductive contacts 272. One or more of the conductive wires 280 may also electrically connect at least one of the semiconductor device 202 and the semiconductor device included in the package 203 to the corresponding conductive contacts 272. The conductive contacts 272 may be external to the package 200, and may be external to the package 203. An exploded view of a portion 282 of the stacked package assembly 100 surrounded by dotted lines is illustrated in FIG. 4 (described further below). The portion 282 includes the conductive bump 292b, the conductive contact 270b, the conductive wire 280b, and the conductive contact 272b.

Still referring to FIG. 2, the package 201 may include a package body 215 including an upper surface 219 and a lateral surface 217. The package body 215 has similar characteristics to those previously described for the package body 214. At least one of the conductive contacts 272 may be disposed adjacent to an external periphery of the package 201. For example, the conductive contacts 272 may be disposed adjacent to the upper surface 219 of the package body 215. In one embodiment, a semiconductor device 222 and a patterned conductive layer 254 may be disposed adjacent to the upper surface 219, where the semiconductor device 222 is electrically connected to the patterned conductive layer 254. One or more of the conductive bumps 291 may be disposed adjacent to the patterned conductive layer 252 and to the patterned conductive layer 254.

As illustrated in FIG. 2, the package body 284 may cover one or more of the semiconductor device 222, the patterned conductive layer 254, the package 200, the package 203, the conductive bumps 292, the conductive bumps 290, the conductive bumps 291, the conductive contacts 272, and the conductive wires 280. In one embodiment, a lateral surface 285 of the package body 284 may be substantially coplanar with the lateral surface 217 of the package body 215.

Still referring to FIG. 2, the conductive contacts 270 may be disposed in at least one row 274. For example, in one embodiment there may be a row 274a of the conductive contacts 270 (oriented into the page) and including the conductive contact 270a, and another row 274b of the conductive contacts 270 (oriented into the page) and including the conductive contact 270b. The row 274b may be substantially aligned with the row 274a. The rows 274 of the conductive contacts 270 may be disposed adjacent to the upper surface 218 of the package body 214, and may be electrically connected to the semiconductor device 204. In addition, the conductive bumps 292 may be disposed in at least one row 294, with each conductive bump 292 being adjacent to a corresponding one of the conductive contacts 270. For example, in one embodiment there may be a row 294a of the conductive bumps 292 (oriented into the page) including the conductive bump 292a, and corresponding to the row 274a of the conductive contacts 270. There may also be a row 294b of the conductive bumps 292 (oriented into the page) including the conductive bump 292b, and corresponding to the row 274b of the conductive contacts 270. The rows 294 of the conductive bumps 292 may be disposed adjacent to the package 203. Each conductive contact 270 and each conductive bump 292 may be electrically connected to a corresponding conductive contact 272 by a corresponding conductive wire 280.

Furthermore, the conductive contacts 290 may be disposed in at least one row 291. For example, in one embodiment there may be a row 291a of the conductive contacts 290 (oriented into the page) and including the conductive contact 290a, and another row 291b of the conductive contacts 290 (oriented into the page) and including the conductive contact 290b. The row 291b may be substantially aligned with the row 291a. At least one of the rows 291 of the conductive contacts 290 may be disposed adjacent to at least one of the rows 294 of the conductive contacts 292. The rows 291 of the conductive contacts 290 may be disposed adjacent to the redistribution unit 250 and to the package 203, and may electrically connect the redistribution unit 250 and the packet 203.

In general, the patterned conductive layer 250, the electrical interconnects 260, the patterned conductive layer 252, and the patterned conductive layer 254 can be formed from a metal, a metal alloy, a matrix with a metal or a metal alloy dispersed therein, or another suitable electrically conductive material. For example, at least one of the patterned conductive layer 250, the electrical interconnects 260, the patterned conductive layer 252, and the patterned conductive layer 254 can be formed from aluminum, copper, titanium, or a combination thereof. The patterned conductive layer 250, the electrical interconnects 260, the patterned conductive layer 252, and the patterned conductive layer 254 can be formed from the same electrically conductive material or different electrically conductive materials.

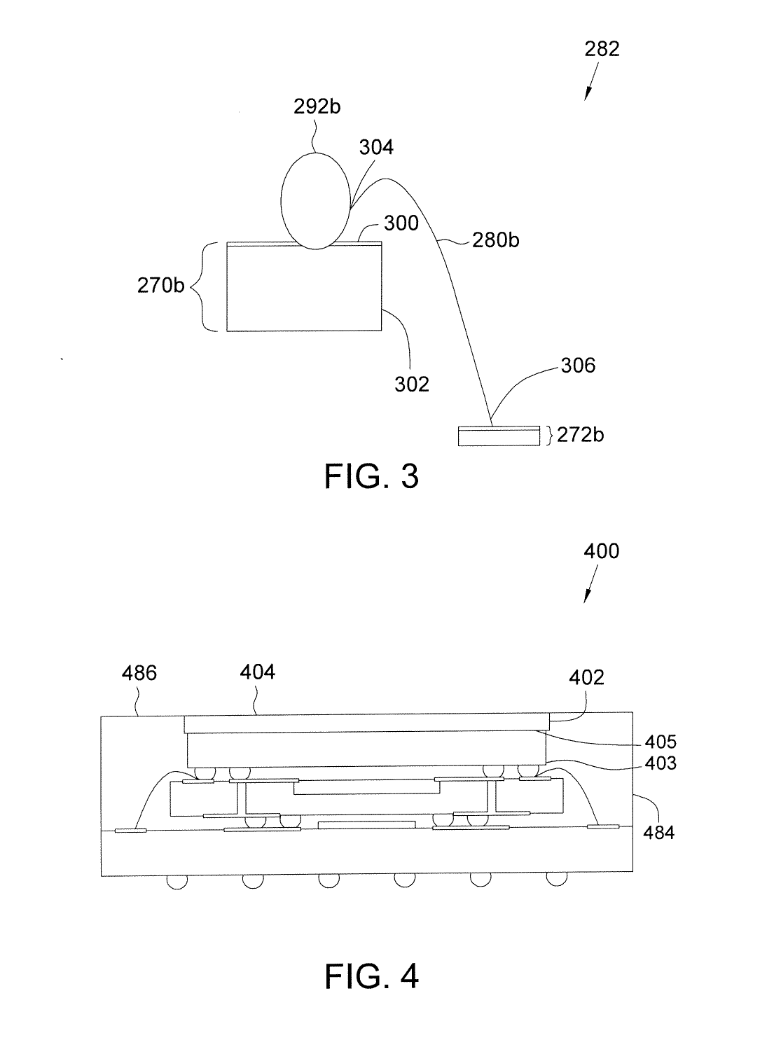

FIG. 3 illustrates an enlarged cross-sectional view of the portion 282 of the stacked package assembly 100 of FIG. 1 including the conductive bump 292b, the conductive wire 280b, and the conductive contacts 270b and 272b, according to an embodiment of the invention. The below description of the portion 282 also applies to other similar structures within the stacked package assembly 100, such as the conductive bump 292a, the conductive wire 280a, and the conductive contacts 270a and 272a. An end 304 of the conductive wire 280b may be disposed adjacent to the conductive contact 270b, and may be at least partially covered by the conductive bump 292b. The attachment of the conductive bump 292b to the end 304 of the conductive wire 280b may take place during a reflow process. An end 306 of the conductive wire 280b may be disposed adjacent to the conductive contact 272b. The ends 304 and 306 of the conductive wire 280b may be attached to the conductive contacts 270b and 272b, respectively, through a wire bonding process. The conductive bump 292b may at least partially cover the wire bond of the end 304 of the conductive wire 280b to the conductive contact 270b. In one embodiment, the conductive wire 280b may be composed of gold, copper, an alloy of metals such as an alloy of silver and gold, or other suitable conductive materials.

The conductive contact 270b includes a layer 300, with the conductive bump 292b being disposed adjacent to the layer 300. In one embodiment, the layer 300 may be an upper layer 300, and the conductive contact 270b may include one or more lower layers 302 below the upper layer 300. Alternatively, the conductive contact 270b may have a single layer 300, without any lower layers 302. In one embodiment, the layer 300 may be based on gold. One example of such a layer is a direct immersion gold finishing layer. The lower layers 302 may include a layer based on nickel, and may also include a layer based on palladium. Examples of combinations of the layer 300 and the lower layers 302 include an electroless nickel/immersion gold finishing layer and an electroless nickel/electroless palladium/immersion gold finishing layer. The conductive contact 272b may have similar characteristics as those of the conductive contact 270b.

As described above, the conductive bump 292b at least partially covers the wire bond of the end 304 of the conductive wire 280b to the conductive contact 270b. This structure can be formed prior to formation of the package body 284 of the stacked package assembly 100 (see FIG. 2) to prevent or reduce wire sweep that may be caused by formation of the package body 284. Although this approach is illustrated in the context of the stacked package assembly 100, it is contemplated that this approach may be used to prevent or reduce wire sweep during formation of stacked package assemblies, such as during encapsulation.

The prevention or reduction of wire sweep during the formation of stacked package assemblies (such as the stacked package assembly 100 shown in FIG. 2) using this approach can result in several advantages. First, the electrical performance of stacked package assemblies can be enhanced, as this approach can reduce and/or eliminate effects such as increased inductance and/or shorting of adjacent wires that can result from wire sweep. Second, the yield of a process used to form stacked package assemblies can be increased due to the prevention and/or reduction of wire sweep during encapsulation. Third, the spacing of conductive wires (such as the conductive wire 280b) can be reduced due to the prevention and/or reduction of wire sweep during encapsulation, which can facilitate the size reduction of stacked package assemblies. Fourth, the number of available conductive wires (such as the conductive wire 280b) can be increased, given the reduction in spacing between wires. Alternatively, the number of conductive wires and the number of conductive contacts (such as the conductive contact 270b) can be reduced because multiple semiconductor device packages can be electrically connected to the same conductive wire 280b. For example, in FIG. 2, the package 200 and the package 203 can both be electrically connected to the conductive wire 280b and to the conductive contact 270b.

FIG. 4 illustrates a cross-sectional view of a stacked package assembly 400, according to another embodiment of the invention. The stacked package assembly 400 is similar to the stacked package assembly 100 (see FIG. 2), except that the stacked package assembly 400 includes a heat sink 402. The stacked package assembly includes a semiconductor device package 403 (similar to the package 203 in FIG. 2) and a package body 484 (similar to the package body 284 in FIG. 2). The package body 484 includes an upper surface 486. The heat sink 402 includes an upper surface 404, and the package 403 includes an upper surface 405. In one embodiment, the heat sink 402 may be adjacent to the upper surface 405. In one embodiment, the upper surface 404 of the heat sink 402 may be substantially coplanar with the upper surface 486 of the package body 484.

While the invention has been described with reference to the specific embodiments thereof, it should be understood by those skilled in the art that various changes may be made and equivalents may be substituted without departing from the true spirit and scope of the invention as defined by the appended claims. In addition, many modifications may be made to adapt a particular situation, material, composition of matter, method, or process to the objective, spirit and scope of the invention. All such modifications are intended to be within the scope of the claims appended hereto. In particular, while the methods disclosed herein have been described with reference to particular operations performed in a particular order, it will be understood that these operations may be combined, sub-divided, or re-ordered to form an equivalent method without departing from the teachings of the invention. Accordingly, unless specifically indicated herein, the order and grouping of the operations are not limitations of the invention.

What is claimed is:

1. A stacked package assembly, comprising:
a first semiconductor device package including:
a first semiconductor device including a back surface and lateral surfaces disposed adjacent to a periphery of the first semiconductor device;
a first package body substantially covering the back surface and the lateral surfaces of the first semiconductor device, the first package body including an upper surface; and
a first conductive contact disposed adjacent to the upper surface of the first package body and electrically connected to the first semiconductor device;
a second semiconductor device package disposed above the upper surface of the first package body;
a first conductive bump disposed adjacent to the first conductive contact and to the second semiconductor device package;
a second conductive contact external to the first semiconductor device package and to the second semiconductor device package; and
a conductive wire electrically connecting the first semiconductor device package and the second semiconductor device package to the second conductive contact, a first end of the conductive wire disposed adjacent to the first conductive contact and at least partially covered by the first conductive bump.

2. The stacked package assembly of claim 1, wherein the first conductive contact includes a plurality of layers including an upper layer adjacent to the first end of the conductive wire, wherein the upper layer includes gold.

3. The stacked package assembly of claim 1, wherein:
the second semiconductor device package includes a second semiconductor device; and
the conductive wire electrically connects the first semiconductor device and the second semiconductor device to the second conductive contact.

4. The stacked package assembly of claim 1, further comprising a third semiconductor device package, and wherein the second conductive contact is disposed adjacent to an external periphery of the third semiconductor device package.

5. The stacked package assembly of claim 1, wherein:
the first semiconductor device includes an active surface; and
at least a portion of the active surface of the first semiconductor device is exposed at the upper surface of the first package body.

6. The stacked package assembly of claim 5, wherein the first semiconductor device package includes:
a first patterned conductive layer adjacent to the upper surface of the first package body; and
an electrical interconnect including a lateral surface, the electrical interconnect extending substantially vertically from the first patterned conductive layer;
wherein:
the lateral surface of the electrical interconnect is substantially covered by the first package body; and
the first semiconductor device is electrically connected to the electrical interconnect and to the first patterned conductive layer.

7. The stacked package assembly of claim 6, wherein the first semiconductor device package includes a second patterned conductive layer adjacent to a lower surface of the first package body and electrically connected to the electrical interconnect.

8. The stacked package assembly of claim 7, further comprising a third semiconductor device package including:
a second package body including an upper surface;
a third semiconductor device disposed adjacent to the upper surface of the second package body; and
a third patterned conductive layer adjacent to the upper surface of the second package body;
wherein the third semiconductor device is electrically connected to the third patterned conductive layer.

9. The stacked package assembly of claim 8, wherein a second conductive bump is disposed adjacent to the second patterned conductive layer and to the third patterned conductive layer.

10. The stacked package assembly of claim 8, further comprising a third package body, wherein the third package body covers:
the third semiconductor device;
the third patterned conductive layer;
the first semiconductor device package;
the first conductive bump;
the second conductive contact; and
the conductive wire.

11. A stacked package assembly, comprising:
a first semiconductor device package including:
a first semiconductor device including a back surface and lateral surfaces disposed adjacent to a periphery of the first semiconductor device;
a first package body substantially covering the back surface and the lateral surfaces of the first semiconductor device, the first package body including an upper surface;
a redistribution unit adjacent to the upper surface of the first package body and extending laterally beyond the periphery of the first semiconductor device, the redistribution unit electrically connected to the first semiconductor device; and
a first conductive contact disposed adjacent to the upper surface of the first package body;
a second semiconductor device package disposed above the upper surface of the first package body;
a first conductive bump disposed adjacent to the first conductive contact and to the second semiconductor device package;
a second conductive bump disposed adjacent to the redistribution unit and to the second semiconductor device package, the second conductive bump electrically connecting the redistribution unit and the second semiconductor device package;
a second conductive contact external to the first semiconductor device package and to the second semiconductor device package; and
a first conductive wire electrically connecting the second semiconductor device package to the second conductive contact, a first end of the conductive wire disposed adjacent to the first conductive contact and at least partially covered by the first conductive bump.

12. The stacked package assembly of claim 11, wherein the first semiconductor device package further comprises a first plurality of conductive contacts including the first conductive contact, the first plurality of conductive contacts: (a) disposed in at least one row; (b) disposed adjacent to the upper surface of the first package body; and (c) electrically connected to the first semiconductor device.

13. The stacked package assembly of claim 12, further comprising:
a first plurality of conductive bumps including the first conductive bump, the first plurality of conductive bumps: (a) disposed in at least one row such that each of the first plurality of conductive bumps is adjacent to a corresponding one of the first plurality of conductive contacts; and (b) disposed adjacent to the second semiconductor device package;
a second plurality of conductive contacts including the second conductive contact, the second plurality of conductive contacts external to the first semiconductor device package and to the second semiconductor device package; and
a plurality of conductive wires including the first conductive wire, each of the plurality of conductive wires electrically connecting the first semiconductor device package and the second semiconductor device package to a corresponding one of the second plurality of conductive contacts, a first end of each of the first plurality of conductive wires: (a) disposed adjacent to a corresponding one of the first plurality of conductive contacts; and (b) at least partially covered by a corresponding one of the first plurality of conductive bumps.

14. The stacked package assembly of claim 13, further comprising:
a second plurality of conductive bumps including the second conductive bump, the second plurality of conductive bumps: (a) disposed in at least one row adjacent to the at least one row of the first plurality of conductive bumps; (b) disposed adjacent to the redistribution unit and to the second semiconductor device package; and (c) electrically connecting the redistribution unit and the second semiconductor device package.

15. The stacked package assembly of claim 14, wherein the each of the first plurality of conductive contacts includes a plurality of layers including an upper layer adjacent to the first end of a corresponding one of the plurality of conductive wires, wherein the upper layer includes gold.

16. The stacked package assembly of claim 14, further comprising a second package body including an upper surface and a lateral surface, wherein the second package body covers:
the first semiconductor device package;
the first plurality of conductive bumps;
the second plurality of conductive contacts;
the plurality of conductive wires; and
the second plurality of conductive bumps.

17. The stacked package assembly of claim 16, further comprising a heat sink including an upper surface, wherein the upper surface of the heat sink is substantially coplanar with the upper surface of the second package body.

18. The stacked package assembly of claim 16, further comprising a third semiconductor device package including a third package body including an upper surface and a lateral surface, wherein:
the second plurality of conductive contacts is disposed adjacent to the upper surface of the third package body; and
the lateral surface of the second package body is substantially coplanar with the lateral surface of the third semiconductor device package.

19. The stacked package assembly of claim 11, wherein:
the redistribution unit includes a first patterned conductive layer adjacent to the upper surface of the first package body;
the first semiconductor device package includes an electrical interconnect including a lateral surface, the electrical interconnect extending substantially vertically from the first patterned conductive layer;
the lateral surface of the electrical interconnect is substantially covered by the first package body; and
the first semiconductor device is electrically connected to the electrical interconnect and to the first patterned conductive layer.

20. The stacked package assembly of claim 19, wherein the first semiconductor device package includes a second patterned conductive layer adjacent to a lower surface of the first package body and electrically connected to the electrical interconnect.
